(19) United States
(12) Patent Application Publication
(10) Pub. No.: US 2026/0157128 A1
(43) Pub. Date: Jun. 4, 2026

(54) PROCESSING METHOD FOR WAFER

(71) Applicant: DISCO CORPORATION, Tokyo (JP)

(72) Inventor: Akira MIZUTANI, Tokyo (JP)

(21) Appl. No.: 19/304,913

(22) Filed: Aug. 20, 2025

(30) Foreign Application Priority Data
Sep. 27, 2024 (JP) 2024-168318

(51) Int. Cl. H01L 21/268; H01L 21/304

(52) U.S. Cl. CPC H10P 34/42; H10P 52/00

(57) ABSTRACT

A processing method for a bonded wafer in which a first wafer and a second wafer are bonded, includes forming a ring-shaped modified layer by focusing and applying a laser beam adjacently inside a chamfered portion formed on an outer periphery of a first wafer; facilitating removal of the chamfered portion by supplying a liquid that weakens a bonding force to an interface between the first wafer and a second wafer bonded together in the chamfered portion and allowing the liquid to penetrate into the interface until the chamfered portion is removable; and grinding the first wafer of the bonded wafer held such that the second wafer faces a chuck table of a griding apparatus, thereby thinning the first wafer and removing the chamfered portion.

### BACKGROUND

### 1. Technical Field

The present disclosure relates to a processing method for a bonded wafer in which a first wafer and a second wafer are bonded, and more specifically to a method of processing the first wafer.

### 2. Description of the Related Art

A wafer, on the front surface of which a plurality of devices, such as ICs and LSIs, are formed demarcated by division lines, is ground on the rear surface to a predetermined thickness, and is then diced into individual device chips by a dicing apparatus and a laser processing apparatus. The device chips are used in electronic appliances, such as portable phones and personal computers.

A chamfer portion is formed on the outer periphery of the wafer, and when the rear surface of the wafer is ground, this chamfered portion may assume a sharp knife-edge shape, where cracks may be initiated and propagate inward, possibly causing damage to the devices formed in the near-center region of the wafer. Further, the knife-edge chamfered portion could harm an operator. To address these problems, a technique has been proposed to remove the chamfer portion of the wafer (see JP2020-88187A).

### SUMMARY

However, in the technique of producing a bonded wafer by bonding a first wafer and a second wafer for the enhancement of device functionality, followed by grinding the rear surface of the first wafer, it is relatively difficult to remove a chamfer portion from the first wafer, for the following reasons.
(1) Since the wafers bonded by a siloxane bond or the like strongly adhere to each other, the chamfered portion is difficult to well remove only by means of a modified layer formed in the first wafer by focusing and applying a laser beam having a wavelength that passes through the first wafer adjacently inside the chamfered portion.
(2) When the modified layer is formed as described above in (1) to facilitate removal of the chamfered portion of the first wafer that strongly adheres to the second wafer, the laser beam applied to form the modified layer could affect and cause damage to the second wafer.
(3) When a cutting blade is used to remove the chamfered portion from the first wafer, it is difficult to completely remove the chamfered portion without damaging the second wafer.

The present disclosure has been made to solve the above-described problems (1) to (3), and it is an object of the present disclosure to provide a processing method for a bonded wafer in which a first wafer and a second wafer are bonded, by which the first wafer is processed so that its chamfered portion can be removed appropriately.

To achieve the aforementioned object, the present disclosure provides a processing method for a bonded wafer in which a first wafer and a second wafer are bonded, by which the first wafer is processed, the method including: forming a ring-shaped modified layer by focusing and applying a laser beam adjacently inside a chamfered portion formed on an outer periphery of the first wafer; facilitating removal of the chamfered portion by supplying a liquid that weakens a bonding force to an interface between the bonded first and second wafers in the chamfered portion and allowing the liquid to penetrate into the interface until the chamfered portion is removable; and grinding the first wafer of the bonded wafer held such that the second wafer faces a chuck table of a griding apparatus, thereby thinning the first wafer and removing the chamfered portion.

It is preferable that the processing method further includes applying an external force to the interface to help weaken the bonding force at the interface during the facilitating removal of the chamfered portion. Further, the forming the modified layer may include: forming a first modified layer at a relatively deep depth so that a crack reaches the interface, by focusing and applying the laser beam in the vicinity of the interface; and forming a second modified layer adjacently outside or inside the first modified layer at a relatively shallow depth not reaching the interface, and an external force may be applied to cause the chamfered portion to bend away from the interface along the first modified layer.

The forming the modified layer may include forming a radial modified layer extending outward from the ring-shaped modified layer. Further, the facilitating removal of the chamfered portion may precede, follow, or coincide with the forming the modified layer.

It is preferable that the first wafer and the second wafer are bonded by a siloxane (Si—O—Si) bond, and the liquid that weakens the bonding force includes any of water, vapor and mist, and the facilitating removal of the chamfered portion weakens the bonding force at the interface by replacing the Si—O—Si bond by an Si—OH—OH—Si bond.

The processing method according to the present disclosure is a processing method for a bonded wafer in which a first wafer and a second wafer are bonded, by which the first wafer is processed. The method includes: forming a ring-shaped modified layer by focusing and applying a laser beam adjacently inside a chamfered portion formed on an outer periphery of the first wafer; facilitating removal of the chamfered portion by supplying a liquid that weakens a bonding force to an interface between the bonded first and second wafers in the chamfered portion and allowing the liquid to penetrate into the interface until the chamfered portion is removable; and grinding the first wafer of the bonded wafer held such that the second wafer faces a chuck table of a griding apparatus, thereby thinning the first wafer and removing the chamfered portion. According to this processing method, since the bonding force in the chamfered portion is weakened before the grinding, the chamfered portion of the first wafer can be removed appropriately. Further, in a case where the facilitation of chamfered portion removal precedes the formation of the modified layer, the chamfered portion can be removed without damage to the second wafer by the laser beam, because the laser beam is blocked by gaps that are formed along with a decrease in adhesion between the first wafer and the second wafer during the facilitation of chamfered portion removal. Furthermore, the processing method of the present disclosure eliminates the use of a cutting blade when removing the chamfered portion, so that the second wafer is free from damage caused by a cutting blade.

### BRIEF DESCRIPTION OF THE DRAWINGS

FIG. 1 is a perspective view of a bonded wafer to be processed in the present embodiment;

FIG. 2 is an overall perspective view of a laser processing apparatus;

FIG. 3 is a perspective view illustrating how the bonded wafer is held on a chuck table of the laser processing apparatus illustrated in FIG. 2;

FIG. 4 is a perspective view illustrating an embodiment of facilitating removal of a chamfered portion;

FIG. 5 is a perspective view illustrating an embodiment of forming a modified layer;

FIG. 6A is a partially enlarged cross-sectional view illustrating a first stage for forming the modified layer, and FIG. 6B is a partially enlarged cross-sectional view illustrating a second stage for forming the modified layer;

FIG. 7 is a plan view of a radial modified layer formed in a first wafer; and

FIG. 8 is a perspective view illustrating an embodiment of grinding.

### DETAILED DESCRIPTION

Preferred embodiments of a processing method for a wafer according to the present disclosure will be described in detail with reference to the accompanying drawings.

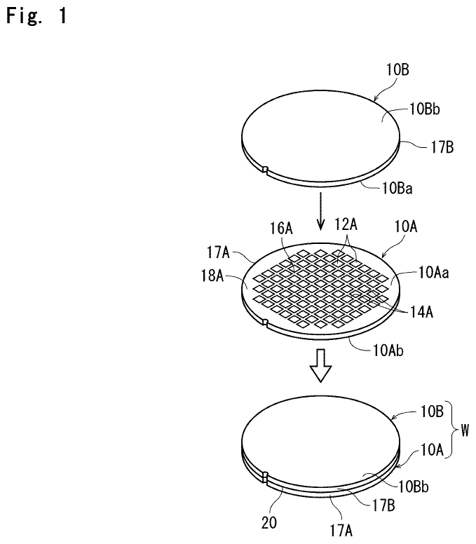

FIG. 1 illustrates a bonded water W, which is an example of a workpiece to be processed in the present embodiment. The bonded wafer W is a wafer in which a first wafer 10A and a second wafer 10B are integrally bonded together. The first wafer 10A is, for example, a silicon (Si) wafer with a diameter of 300 mm and a thickness of 300 μm, on a front surface 10Aa of which a plurality of devices 12A are formed demarcated by division lines 14A. The first wafer 10A has the front surface 10Aa and a rear surface 10Ab, and includes an effective region 16A located near the center of the wafer, in which the devices 12 for use as products are formed, and an outer peripheral surplus region 18A surrounding the effective region 16A, on the outer periphery of which a chamfered portion 17A is formed. The second wafer 10B is also a silicon (Si) wafer with the same structure as the first wafer 10A, including a chamfered portion 17B formed on its outer periphery and, although not illustrated in the drawing, an effective region formed on its front surface 10Ba directed downward in the drawing, in which a plurality of devices are formed demarcated by division lines. The bonded wafer W of the present embodiment is produced, for example, by integrally bonding the first wafer 10A and the second wafer 10B such that the front surface 10Aa and the front surface 10Bb face each other with an interface 20 therebetween formed by a siloxane bond. The siloxane bond is an Si—O—Si bond formed between alternating silicon (Si) and oxygen (O) atoms. Since the first wafer 10A and the second wafer 10B are bonded by heat treatment, they remain strongly bonded even at high temperatures.

The processing method of the present embodiment for processing the first wafer 10A of the bonded wafer W includes: forming a ring-shaped modified layer by focusing and applying a laser beam adjacently inside the chamfered portion 17A formed on the outer periphery of the first wafer 10A; and facilitating removal of the chamfered portion 17A by supplying a liquid that weakens the bonding force to the interface 20 between the bonded first and second wafers 10A and 10B in the vicinity of the chamfered portions 17A and 17B and allowing the liquid to penetrate into the interface 20 until the chamfered portion 17A of the first wafer 10A is removable.

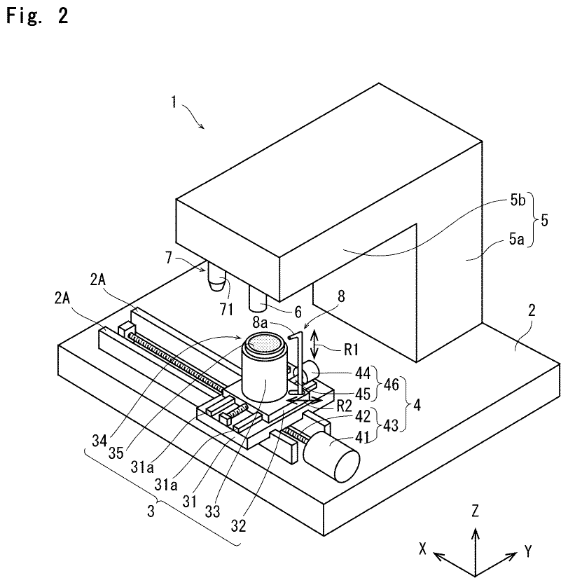

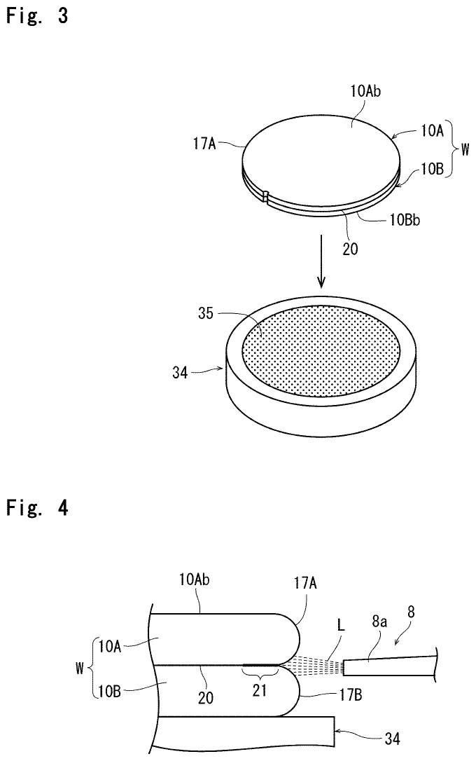

FIG. 2 illustrates a laser processing apparatus 1 that is configured to form the modified layer and facilitate removal of the chamfered portion as described in the present embodiment.

The laser processing apparatus 1 placed on a base 2 includes a holding unit 3 that holds the bonded wafer W, a moving unit 4 that moves the holding unit 3, an alignment unit 6 that images the bonded wafer W held by the holding unit 3 so that it is properly aligned, a laser beam applying unit 7 that applies a laser beam to the bonded wafer W held by the holding unit 3, a frame 5 that includes a vertical wall portion 5a standing on the side of the moving unit 4 and a horizontal wall portion 5b extending horizontally from the upper end of the vertical wall portion 5a, and a liquid supply unit 8.

As illustrated in FIG. 2, the holding unit 3 includes an X-axis direction movable plate 31 that is rectangular in shape and is mounted on the base 2 movably in the X axis direction, a Y-axis direction movable plate 32 that is rectangular in shape and is placed on the X-axis direction movable plate 31 movably in the Y axis direction, a support 33 that is cylindrical in shape and is fixed to the upper surface of the Y-axis direction movable plate 32, and a chuck table 34 placed at the upper end of the support 33. The chuck table 34 is configured to be rotatable by a rotary drive unit (not illustrated) housed inside the support 33 and includes a suction chuck 35 made of a breathable porous material on the upper surface of the chuck table 34. The suction chuck 35 is connected to a suction unit (not illustrated) via a flow passage passing through the support 33. When the suction unit is operated, negative pressure is generated on the upper surface of the suction chuck 35, so that the bonded wafer W can be held by suction.

The moving unit 4 includes an X-axis moving unit 43 that moves the holding unit 3 in the X axis direction, and a Y-axis moving unit 46 that moves the holding unit 3 in the Y axis direction orthogonal to the X axis direction. The X-axis moving unit 43 converts the rotational movement of a motor 41 into liner movement via a ball screw 42 and conveys it to the X-axis direction movable plate 31, thereby moving the X-axis direction movable plate 31 in the X axis direction along a pair of guide rails 2A, 2A provided on the base 2 in the X axis direction. The Y-axis moving unit 46 converts the rotational movement of a motor 44 into liner movement via a ball screw 45 and conveys it to the Y-axis direction movable plate 32, thereby moving the Y-axis direction movable plate 32 along a pair of guide rails 31a, 31a provided on the X-axis direction movable plate 31 in the Y axis direction.

An optical system of the laser beam applying unit 7 is housed inside the horizontal wall portion 5b of the frame 5. On the lower surface of a front end part of the horizontal wall portion 5b, a condenser 71, which is a part of the laser beam applying unit 7, is provided to condense and apply a laser beam having a wavelength that passes through at least the first wafer 10A to the bonded wafer W. The alignment unit 6 is located adjacent to the condenser 71 in the X axis direction. The alignment unit 6 is an imaging unit that images the bonded wafer W held by the holding unit 3 to detect the location and orientation of the bonded wafer W, the laser processing position where the laser beam should be applied, and the like.

The liquid supply unit 8 of the present embodiment is placed on the Y-axis direction movable plate 32 adjacent to the chuck table 34. The liquid supply unit 8 includes a nozzle 8a at its upper end, which is connected to a liquid supply source (not illustrated) from which a liquid L is supplied. The liquid supply unit 8 is configured to be movable by a drive unit (not illustrated) in the vertical direction indicated by the arrow R1 and in the direction toward the center of the chuck table 34 indicated by the arrow R2, so that the nozzle 8a can be located at a desired position for allowing the liquid L to be sprayed from the tip of the nozzle 8a.

The laser processing apparatus 1 also includes, in addition to the above-described components, a control unit that controls the respective operating units, a display unit, and the like (not illustrated). The control unit is composed of a computer including a central processing unit (CPU) that performs arithmetic operations according to a control program, a read-only memory (ROM) that stores the control program and the like, a random-access memory (RAM) or read and write memory that temporarily stores data such as detected values and operation results, an input interface, and an output interface (not illustrated). The control unit is connected to the moving unit 4, the alignment unit 6, the laser beam applying unit 7, the display unit (not illustrated) and the like.

The laser processing apparatus 1 of the present embodiment basically includes the above-described components. The following is a description of the processing method for a wafer according to the present disclosure, including forming the modified layer and facilitating removal of the chamfered portion removal, followed by grinding (to be described later).

The modified layer can be formed using the laser processing apparatus 1, and the facilitation of chamfered portion removal can precede, follow, or coincide with the formation of the modified layer. Herein, a description is given of a case where the facilitation of chamfered portion removal precedes the formation of the modified layer.

### Facilitation of Chamfered Portion Removal

The bonded wafer W described with reference to FIG. 1 is prepared and conveyed to the laser processing apparatus 1 described with reference to FIG. 2 such that it is placed on the suction chuck 35, which serves as a holding surface of the chuck table 34, with the first wafer 10A facing upward and the second wafer 10B facing downward. Although not illustrated in the drawings, protective tape may be applied to the rear surface 10Bb of the second wafer 10B when it is necessary to prevent the liquid L, which is supplied for the facilitation of chamfered portion removal, from being sucked by negative pressure generated on the suction chuck 35 of the chuck table 34. The protective tape is preferably slightly larger than the suction chuck 35 so that it can cover at least the whole of the illustrated suction chuck 35.

When the bonded wafer W is placed on the chuck table 34, the suction unit (not illustrated) is operated to generate negative pressure on the suction chuck 35, so that the bonded wafer W is held by suction. Then, the liquid supply unit 8 is moved in the vertical direction indicated by the arrow R1 and in the direction toward the center of the chuck table 34 indicated by the arrow R2 in FIG. 1 so that the tip of the nozzle 8a of the liquid supply unit 8 is located at the level of the interface 20 between the bonded first and second wafers 10A and 10B and in proximity to the side of the interface 20.

Thereafter, the liquid L that weakens the bonding force at the interface 20 between the chamfered portion 17A of the first wafer 10A and the chamfered portion 17B of the second wafer 10B bonded together is supplied from the tip of the nozzle 8a to the interface 20, while the chuck table 34 is rotated. When the liquid L (e.g., pure water) is supplied laterally to the interface 20, which is bonded by a siloxane bond (Si—O—Si bond) in the present embodiment as described above, water molecules gradually penetrate into the interface 20 from the outer periphery, causing the Si—O—Si bond at the penetrated interface to be replaced by an Si—OH—OH—Si bond. As a result, the bonding force at the interface 20 is weakened, resulting in the formation of a ring-shaped reduced bonding force region 21 at the interface 20 between the bonded chamfered portions 17A and 17B as illustrated in FIG. 4. The liquid L supplied from the nozzle 8a is not limited to pure water (in liquid form) and may be in the form of vapor or mist.

In the present embodiment, the liquid L is sprayed under high pressure from the nozzle 8a of the liquid supply unit 8. As such, the liquid L also serves as an external force that causes the chamfered portion 17A of the first wafer 10A to bend away from the chamfered portion 17B of the second wafer 10B by hydraulic pressure. In other words, the liquid supply unit 8 also functions as an external force applying unit that applies an external force to weaken the bonding force at the interface 20. In this manner, the liquid L sprayed under high pressure facilitates removal of the chamfered portion and, at the same time, serves as an external force that weakens the bonding force at the interface 20. Consequently, the change in the bonding state at the interface 20 (as described above) combined with the external force applied through the high-pressure spray of the liquid L makes it possible to more reliably form the reduced bonding force region 21 with decreased adhesion. The reduced bonding force region 21 is formed not to reach the effective region 16A where the devises 12A are formed. To this end, the reduced bonding force region 21 is formed to have a desired width at the interface 20 on the outer periphery by appropriately adjusting the amount and spray pressure of the liquid L to be supplied, the rotating speed of the chuck table 34, the length of time during which the liquid L is supplied, and the like.

### Formation of Modified Layer

The facilitation of chamfered portion removal as described above is followed by the formation of the modified layer as described below. For the formation of the modified layer, the bonded wafer W held by suction on the chuck table 34 is aligned by the alignment unit 6 of the laser processing apparatus 1. More specifically, the alignment unit 6 detects the location of the outer peripheral edge of the first wafer 10A where the chamfered portion 17A is formed, the center position of the first wafer 10A, and the height of the upper surface of the rear surface 10Ab of the first wafer 10A, thereby locating the laser processing position where a laser beam LB should be focused and applied, adjacently inside the chamfered portion 17A formed on the outer periphery of the first wafer 10A (e.g., at a radius of 147 mm from the center point of the first wafer 10A).

In the present disclosure, the modified layer can be formed, for example, in two stages as described below.

### First Stage

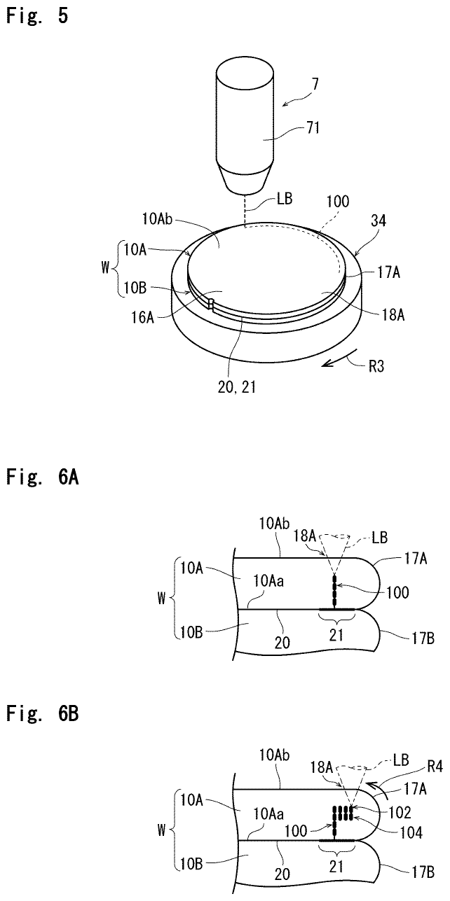

Based on the information on the laser processing position detected by the alignment unit 6, the chuck table 34 is moved so that the laser processing position set in the first wafer 10A of the bonded wafer W is located directly beneath the condenser 71 of the laser beam applying unit 7 as illustrated in FIG. 5. Then, as will be understood from FIG. 5 and FIG. 6A, the laser beam LB is focused and applied to the processing position in the first wafer 10A, while the chuck table 34 is rotated in the direction indicated by the arrow R3 in FIG. 5, thereby forming a first ring-shaped modified layer 100 inside the chamfered portion 17A of the first wafer 10A along the entire circumference.

The first modified layer 100 formed in the first stage of the present embodiment is preferably composed of a plurality of layers arranged vertically as illustrated in FIG. 6A. For example, the first modified layer 100 illustrated in FIG. 6A is composed of four vertically arranged modified layers. For the formation of the first modified layer 100 including the plurality of layers, the laser beam LB is initially focused and applied to a deeper part (e.g., at a depth of 180 μm from the rear surface 10Ab) of the first wafer 10A that is set closer to the interface 20 adjacently inside the chamfered portion 17A, while the chuck table 34 is rotated in the direction indicated by the arrow R3, thereby forming one of the four ring-shaped modified layers along the chamfered portion 17A. Thereafter, the focusing point of the laser beam LB is moved (upward) three times toward the rear surface 10Ab, for example, such that the focusing point is located at a depth of 170 μm, 160 μm and then 150 μm from the rear surface 10Ab, while the chuck table 34 is rotated, thereby forming the remaining three ring-shaped modified layers along the chamfered portion 17A. In this manner, the first modified layer 100 is formed at a relatively deep depth in the first wafer 10A by focusing and applying the laser beam LB to the positions closer to the interface 20. As a result, cracks develop in the first wafer 10A along the first modified layer 100 and propagate until they reach the front surface 10Aa, i.e., the interface 20. In FIG. 6, the first modified layer 100 is illustrated conceptually for explanatory convenience; thus, the depth of each of the layers is not based on the actual dimensions. The first stage is thus completed. The first modified layer 100 formed in the first stage may not be composed of four layers and may include an appropriate number of layers depending on the wavelength and output of the laser beam LB applied by the laser beam applying unit 7, the thickness and material of the first wafer 10A, and the like.

### Second Stage

The first stage where the first modified layer 100 is formed is followed by a second stage where second modified layers are formed outside or inside the first modified layer 100 at relatively shallow depths not reaching the interface 20 of the bonded wafer 20. In the second stage of the present embodiment, as illustrated in FIG. 6B, the laser beam LB is focused and applied to positions adjacently outside the uppermost modified layer (formed at a depth of 150 μm from the rear surface 10Ab) and the second uppermost modified layer (formed at a depth of 160 μm from the rear surface 10Ab) of the first modified layer 100, while the chuck table 34 is rotated, thereby forming ring-shaped second modified layers 102 and 104. As illustrated in the drawing, each of the second modified layers 102 and 104 is preferably composed of a plurality of (e.g., three in the illustrated embodiment) diametrically adjacent modified layers formed at the same depth.

During the formation of the modified layer, the first stage where the first modified layer 100 is formed is followed by the second stage where the second modified layers 102 and 104 are formed adjacent to the first modified layer 100 at relatively shallow depths not reaching the interface 20. This allows an external force to be applied to cause the chamfered portion 17A to bend away from the interface 20 in the direction indicated by the arrow R4 along the first modified layer 100 as illustrated in FIG. 6B. As a result, the bonding force in the reduced bonding force region 21 formed at the interface 20 can be reduced more reliably, and the cracks initiated from the first modified layer 100 during the formation of the first modified layer 100 are allowed to develop further.

The formation of the modified layer is thus completed. In the above-described embodiment, the second modified layers 102 and 104 are formed adjacently outside the first modified layer 100. However, the present disclosure is not limited thereto, and the second modified layers 102 and 104 may be formed adjacently inside the first modified layer 100, in which case an external force can be equally applied in the direction indicated by the arrow R4 to cause the chamfered portion 17A to bend away from the interface 20 along the first modified layer 100, as in the case where the second modified layers 102 and 104 are formed outside.

Each of the second modified layers formed in the second stage may not be composed of three ring-shaped modified layers and may include two or less or four or more modified layers.

The modified layer is formed, for example, under the following laser processing conditions 1 or 2.

### Laser Processing Conditions 1

Wavelength: 1099 nm
Repetition frequency: 80 kHz
Average output: 2.0 W
Processing feed rate: 450 mm/s

### Laser Processing Conditions 2

Wavelength: 1342 nm
Repetition frequency: 90 kHz
Average output: 1.9 W
Processing feed rate: 400 mm/s

In a case where the first stage and the second stage are performed under the laser processing conditions 2, the depths of the modified layers are preferably set slightly deeper than those of the modified layer 100 and the modified layers 102 and 104. More specifically, in the first stage, the laser beam LB is focused and applied to a position at a depth of, for example, 183 μm from the rear surface 10Ab in the first wafer 10A, which is set closer to the interface 20 adjacently inside the chamfered portion 17A, while the chuck table 34 is rotated, thereby forming one of the four ring-shaped modified layers along the chamfered portion 17A. Thereafter, the focusing point of the laser beam LB is moved (upward) three times toward the rear surface 10Ab, for example, such that the focusing point is located at a depth of 173 μm, 163 μm and then 153 μm from the rear surface 10Ab, while the chuck table 34 is rotated, thereby forming the remaining three ring-shaped modified layers along the chamfered portion 17A. Then, the second stage follows, where the modified layers 102 and 104 are formed at the same depths as those of the uppermost and second uppermost modified layers formed in the first stage, i.e., at depths of 153 μm and 163 μm from the rear surface 10Ab, respectively.

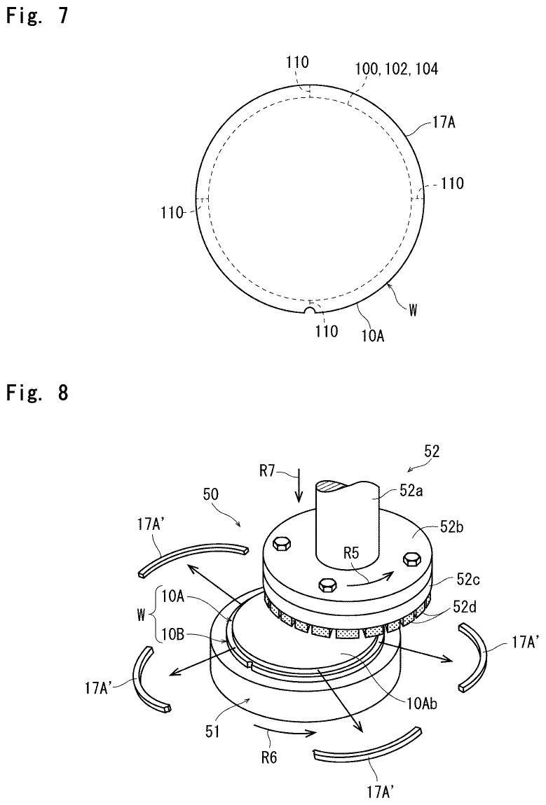

During the formation of the modified layer, a radial modified layer 110, for example, may also be formed to extend outward toward the chamfered portion 17A from the region where the first modified layer 100 is formed, as illustrated in FIG. 7. The illustrated modified layer 110 helps to break up the ring-shaped chamfered portion 17A into smaller pieces when the chamfered portion 17A is removed. The modified layer 110 is formed, for example, at a plurality of (e.g., four in the illustrated embodiment) locations spaced equally on the outer periphery of the first wafer 10A by applying the laser beam LB under the same laser processing conditions as those for forming the first modified layer 100. When the chamfered portion 17A is removed from the first wafer 10A during grinding (to be described later), the thus-formed modified layer 110 helps to segment the chamfered portion 17A into a plurality of pieces 17A′, resulting in better removal of the chamfered portion 17A.

In the above-described embodiment, the facilitation of chamfered portion removal precedes the formation of the modified layer. The facilitation of chamfered portion removal involves the formation of the reduced bonding force region 21 at the interface 20 on the outer periphery of the bonded wafer W, resulting in decreased adhesion and formation of small gaps. As such, even though the modified layer is formed by focusing and applying the laser beam LB to a relatively deep part of the first wafer 10A, the laser beam LB is prevented from affecting the second wafer 10B because the gaps block the laser beam, thereby avoiding damage to the second wafer 10B. Moreover, the chamfered portion 17A can be removed reliably without cutting machining using a cutting blade, so that the second wafer 10B is free from damage caused by a cutting blade.

In the above-described embodiment, the formation of the modified layer follows the facilitation of chamfered portion removal. However, in a case where the modified layer is formed in the first and second stages as described with reference to FIGS. 6A and 6B, the formation of the modified layer may effectively precede the facilitation of chamfered portion removal, which involves supplying the liquid L for weakening the bonding force to the interface 20. More specifically, prior to the facilitation of chamfered portion removal, the modified layer may be formed in the first and second stages so that the second modified layers 102 and 104 formed in the second stage can serve to produce an external force that causes the chamfered portion 17A to bend away from the interface 20 along the first modified layer 100. Then, the facilitation of chamfered portion removal may follow, where the liquid L for weakening the bonding force is supplied from the outer peripheral side of the bonded wafer W to the interface 20 between the bonded first and second wafers 10A and 10B. As a result, it becomes possible to efficiently weaken the bonding force at the interface 20 on the outer periphery, because the liquid L is combined with the external force produced by the formation of the modified layer to cause the chamfered portion 17A to bend away from the interface 20.

Alternatively, the formation of the modified layer may coincide with the facilitation of chamfered portion removal in the present disclosure. Considering in particular the configuration of the laser processing apparatus 1 in which the liquid supply unit 8 is located adjacent to the chuck table 34 of the holding unit 3, the formation of the modified layer and the facilitation of chamfered portion removal can coincide, and they can also be accompanied by the application of the external force to the interface 20 by means of the liquid L supplied by the liquid supply unit 8.

### Grinding

In the present disclosure, the formation of the modified layer and the facilitation of chamfered portion removal are followed by grinding, where the first wafer 10A of the bonded wafer W is ground on the rear surface 10Ab to be thinned and the chamfered portion 17A of the first wafer 10A is removed.

The bonded wafer W, after the formation of the modified layer and the facilitation of chamfered portion removal, is conveyed to a grinding apparatus 50 (only partly) illustrated in FIG. 8. As illustrated in the drawing, the griding apparatus 50 includes a grinding unit 52 that grinds and thins the bonded wafer W held by suction on a chuck table 51. The grinding unit 52 includes a rotating spindle 52a that is rotated by a rotary drive mechanism (not illustrated), a wheel mount 52b mounted at the lower end of the rotating spindle 52a, and a grinding wheel 52c attached to the lower surface of the wheel mount 52b with a plurality of grinding stones 52d mounted annularly on the lower surface of the grinding wheel 52c.

The bonded wafer W conveyed to the grinding apparatus 50 is placed on the chuck table 51 with the second wafer 10B facing downward, and the suction unit (not illustrated) is operated to hold the bonded wafer W by suction. Then, the rotating spindle 52a of the grinding unit 52 is rotated in the direction indicated by the arrow R5 in FIG. 8 at a speed of, for example, 6000 rpm, while the chuck table 51 is rotated in the direction indicated by the arrow R6 at a speed of, for example, 300 rpm. Thereafter, a grinding water supply unit (not illustrated) supplies grinding water onto the rear surface 10Ab of the first wafer 10A, while a grinding feed unit (not illustrated) is operated to feed the grinding wheel 52c downward in the direction indicated by the arrow R7 at a grinding feed rate of, for example, 0.1 μm, with the grinding stones 52d brought into contact with the rear surface 10Ab of the first wafer 10A. During the grinding, the thickness of the bonded wafer W is measured with a contact/non-contact measurement gauge (not illustrated), so that the bonded wafer W can be thinned to a desired thickness.

Although not illustrated in the drawings, the grinding can be performed in two stages, e.g., rough grinding and finish grinding. For example, the grinding apparatus 50 may include a rough grinding unit including a grinding wheel with grinding stones for rough grinding and a fine finish grinding unit that includes a grinding wheel with grinding stones for finish grinding, so that the rear surface 10Ab of the first wafer 10A can be rough-ground with the rough grinding wheel, and sequentially be finish-ground with the finish grinding wheel.

As illustrated in FIG. 8, the grinding serves not only to thin the first wafer 10A of the bonded wafer W but also to remove the chamfered portion 17A along the modified layer 100 in the form of the pieces 17A′ under an external force applied to the first wafer 10A to remove the chamfered portion 17A. In the present embodiment where the radial modified layer 110 is formed, the chamfered portion 17A is broken into the plurality of pieces 17A′ along the radial modified layer 110 when being removed from the first wafer 10A during the grinding, resulting in better removal of the chamfered portion 17A.

When the bonded wafer W with a desired thickness is obtained by grinding the rear surface 10Ab of the first wafer 10A by a predetermined amount and removing the chamfered portion 17A, the grinding unit 52 is stopped and retracted upward, and the grinding is completed. The grinding may be appropriately followed by, for example, washing and drying the bonded wafer W from which the chamfered portion 17A has been removed, which will not be described herein.

The above-described bonded wafer W is a wafer in which the first wafer 10A and the second wafer 10B are bonded by a siloxane bond. However, the bond between the first and second wafers 10A and 10B of the bonded wafer W to be processed in the present disclosure is not limited to the siloxane bond. Examples of the bond between the first and second wafers 10A and 10B include an SiCN bond (nitride bond), a TEOS bond where a tetraethyl orthosilicate molecule is converted into a solid state with an Si—O—Si bond, and a ThOx bond where silicon surface is heated in an oxidizing atmosphere to form a thermally oxidized film. Any of these bonds can be weakened by the liquid L supplied for the facilitation of chamfered portion removal, so that the chamfered portion 17A can be equally removed by the above-described processing method for a wafer. Further, the present disclosure is also applicable to a bonded wafer W in which the bonded surface forming the interface 20 has been pretreated with O₂ plasma or N₂ plasma. Furthermore, the liquid L is not limited to pure water and may be a liquid mixture mixed with another liquid containing water molecules.

### REFERENCE SIGNS LIST

1 Laser processing apparatus
2 Base
3 Holding unit
31 X-axis direction movable plate
32 Y-axis direction movable plate
34 Chuck table
35 Suction chuck
4 Moving unit
43 X-axis moving unit
46 Y-axis moving unit
5 Frame
6 Alignment unit
7 Laser beam applying unit
71 Condenser
8 Liquid supply unit
8a Nozzle
10A First wafer
10Aa Front surface
10Ab Rear surface
12A Device
14A Division line
16A Effective region
17A Chamfered portion
18A Outer peripheral surplus region
10B Second wafer
10Ba Front surface
10Bb Rear surface
20 Interface
21 Reduced bonding force region
50 Grinding apparatus
51 Chuck table
52 Grinding unit
52a Rotating spindle
52b Wheel mount
52c Grinding wheel
52d Grinding stone
100 First modified layer
102, 104 Second modified layer
110 Radial modified layer
L Liquid (pure water)
W Bonded wafer

What is claimed is:

1. A processing method for a bonded wafer in which a first wafer and a second wafer are bonded, by which the first wafer is processed, the method comprising:
forming a ring-shaped modified layer by focusing and applying a laser beam adjacently inside a chamfered portion formed on an outer periphery of the first wafer;
facilitating removal of the chamfered portion by supplying a liquid that weakens a bonding force to an interface between the bonded first and second wafers in the chamfered portion and allowing the liquid to penetrate into the interface until the chamfered portion is removable; and
grinding the first wafer of the bonded wafer held such that the second wafer faces a chuck table of a griding apparatus, thereby thinning the first wafer and removing the chamfered portion.

2. The processing method of claim 1, further comprising applying an external force to the interface to help weaken the bonding force at the interface during the facilitating removal of the chamfered portion.

3. The processing method of claim 2, wherein
the forming the modified layer includes: forming a first modified layer at a relatively deep depth so that a crack reaches the interface, by focusing and applying the laser beam in the vicinity of the interface; and forming a second modified layer adjacently outside or inside the first modified layer at a relatively shallow depth not reaching the interface, and
an external force is applied to cause the chamfered portion to bend away from the interface along the first modified layer.

4. The processing method of claim 1, wherein the forming the modified layer includes forming a radial modified layer extending outward from the ring-shaped modified layer.

5. The processing method of claim 1, wherein the facilitating removal of the chamfered portion precedes, follows, or coincides with the forming the modified layer.

6. The processing method of claim 1, wherein
the first wafer and the second wafer are bonded by a siloxane (Si—O—Si) bond, and the liquid that weakens the bonding force comprises any of water, vapor and mist, and
the facilitating removal of the chamfered portion weakens the bonding force at the interface by replacing the Si—O—Si bond by an Si—OH—OH—Si bond.
